(19) United States
(12) Patent Application Publication
(10) Pub. No.: US 2007/0290263 A1
(43) Pub. Date: Dec. 20, 2007

(54) SEMICONDUCTOR DEVICE AND METHOD FOR MANUFACTURING THE SAME

(75) Inventor: Yoshiki KAMATA, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/683,062

(22) Filed: Mar. 7, 2007

(30) Foreign Application Priority Data
Jun. 19, 2006 (JP) 2006-168738

(51) Int. Cl. H01L 27/12; H01L 21/20; H01L 21/84

(52) U.S. Cl. 257/347; 438/479; 257/E27.111; 257/E21.09; 438/154; 257/E21.704

(57) ABSTRACT

It is made possible to obtain epitaxially grown layers with excellent crystallinity. A semiconductor device includes: a semiconductor layer having crystallinity; a first insulating film formed on the semiconductor layer and having a first opening to reach the semiconductor layer; a first epitaxially grown layer formed on the first insulating film so as to embed the first opening; a second insulating film formed on the first epitaxially grown layer and having a second opening to reach the first epitaxially grown layer; and a second epitaxially grown layer formed on the second insulating film so as to embed the second opening.

### CROSS-REFERENCE TO RELATED APPLICATION

This application is based upon and claims the benefit of priority from prior Japanese Patent Application No. 2006-168738 filed on Jun. 19, 2006 in Japan, the entire contents of which are incorporated herein by reference.

### BACKGROUND OF THE INVENTION

1. Field of the Invention

The present invention relates to a semiconductor device and a method for manufacturing the semiconductor device.

2. Related Art

There have been known techniques for forming semiconductor crystal layers on insulating films such as SiO₂ films. Devices formed on SiO₂ films are known as SOI (silicon on insulator) devices, and have been used as low-power-consumption devices in recent years. SOI substrates to be used in SOI devices are produced by methods involving the entire substrate surface, such as a bonding method, the SIMOX method, and the ELTRAN method. Such SOI substrates have been put on the market. A single-crystal region of Si on a SiO₂ film in a local region in the substrate plane is produced by forming an opening in the SiO₂ film and epitaxially growing the single-crystal region of Si located below the SiO₂ film so as to expand the single-crystal region of Si onto the SiO₂ film (horizontal epitaxial growth). However, the crystallinity of the epitaxially grown layer formed in this manner is poorer than the crystallinity of a SOI substrate formed by a bonding method, and the epitaxially grown layer is not suited for practical use.

To obtain high-speed operations, devices have been made smaller and smaller. However, the reduction in device size is about to reach the limit. Once the reduction in device size reaches the limit, the operation speed might be increased by using a semiconductor material other than Si or using a different plane orientation of Si. In the former case, Ge or a compound semiconductor may be used as a semiconductor material, because Ge or a compound semiconductor has higher mobility than Si. In the latter case, an n-type MOSFET and a p-type MOSFET are formed on Si substrates having different plane orientations from each other. For example, an n-type MOSFET is formed on a Si substrate having the (100) plane orientation, while a p-type MOSFET is formed on a Si substrate having the (110) plane orientation.

First, the background art of devices formed on Ge substrates is described. CMOS devices are necessary to produce low-power-consumption devices. A good insulating protection film can be formed with Ge, and only Ge has higher electron mobility and higher hole mobility than Si. Accordingly, CMOS devices are expected on Ge substrates. In a case where a CMOS device is formed on a Ge substrate, however, analog devices such as an I/O unit should preferably be formed on a Si substrate. Therefore, a device formed on a Si semiconductor and a device formed on a Ge semiconductor need to be mounted together. In a case where a device formed on a Si semiconductor and a device formed on a Ge semiconductor are mounted together, a Si semiconductor region and a Ge semiconductor region may be formed in one substrate beforehand, as disclosed in JP-A 2006-12995 (KOKAI). However, the melting points of Si and Ge are different from each other, being 1415° C. and 937° C., respectively. Because of this, the heat treatment temperatures for activating conductive impurities (dopant) are different between the Si semiconductor region and the Ge semiconductor region. As a result, the production processing temperatures of the respective devices are different, causing a processing temperature mismatch, which poses difficulties in the device production.

To counter the above problem, after a device is formed on a Si substrate, a Ge region may be formed on the Si substrate through local epitaxial growth. For instance, the formation of a Ge region by LPE (Liquid Phase Epitaxy) is discussed in Appl. Phys. Lett, 84, 2563 (2004) (Y. Lin, et al.). A Ge region formed by this method reportedly has excellent crystallinity. However, the lattice constants of Si and Ge are different from each other, being 0.543 nm and 0.565 nm, respectively. As a result, the crystallinity of Ge in the vicinity of the interface between the Si substrate and the Ge region is poor, and a device should be formed in a region other than this region. Because of this, the area in which a device can be formed is reduced, and high integration of devices cannot be expected.

Meanwhile, Tech. Dig. Int. Electron Devices Meet. 20.7 (2005) (E. A. Fitzgerald, et al.) discloses a method by which a device region is surrounded by a region formed with an insulating film, so as to improve the crystallinity of the device region. This is based on the fact that crystallinity defects can be terminated with the sidewalls made by insulating films by increasing the thickness of the region made by the insulating films, as disclosed in T. A. Langdo, et al., Appl. Phys. Lett. 76, 3700 (2000). However, as far as the report about the crystallinity in E. A. Fitzgerald, et al., Tech. Dig. Int. Electron Devices Meet. 20.7 (2005) is concerned, the improvement of crystallinity is limited, and the poor crystallinity remains a problem in terms of yield.

Also, the use of a buried oxide film (BOX film) as an insulating film on a SOI substrate may be considered. However, the thickness of a BOX layer used in a SOI device might be smaller than the exposure limit F. With such a BOX layer, it is difficult to establish the relationship, h>1, which should be established between the film thickness h of a SiO₂ film and the opening width I (≧F) of the epitaxial region surrounded by the SiO₂ film, as disclosed in T. A. Langdo, et al., Appl. Phys. Lett. 76, 3700 (2000). Since the lattice constants at a regular hetero-junction between Si and Ge are different from each other, the stress and the strain energy at the interface are large. To release the strain energy and obtain lattice relaxation, crystalline defects are caused at the interface. The crystal lattice of a diamond structure such as Si or Ge characteristically has the (111) plane as a slip plane, and easily causes dislocation of the (111) plane in the [110] direction. The angle of the (111) plane with respect to the (100) plane is 54.70, while the angle of the [110] direction of the dislocation of the slip plane with respect to the (100) plane is 45°. The dislocation is movable in the slip plane, and the geometric relationship between the opening width I and the film thickness h of the SiO₂ film to terminate the crystalline defects caused at the Si/Ge hetero-junction with the sidewalls of the SiO₂ film is defined as h>1 in T. A. Langdo, et al., Appl. Phys. Lett. 76, 3700 (2000).

Next, the background art of CMOS devices formed on Si substrates having different plane orientations is described. Conventionally, devices have been formed on Si substrates having the (100) plane orientation of the smallest interface state. However, since it was proved that the mobility was improved when a channel was directed in the [110] direction of a Si substrate having the (110) plane orientation, the use of different plane orientations has been considered. As epitaxial growth reflects the crystallinity of the seed portion, it is difficult to produce channels having different plane orientations on the same substrate. JP-A 2006-12995 (KOKAI) discloses an example case where a Si semiconductor layer having the (100) plane orientation and a Si semiconductor layer having the (110) plane orientation are formed on the same substrate by a bonding method. To reduce the production costs, epitaxial growth is more suitable than the bonding method disclosed in JP-A 2006-12995 (KOKAI). In a case where epitaxial growth is performed, the epitaxially grown layer needs to have excellent crystallinity, so as to operate the device formed on the epitaxially grown layer at a high speed.

As described above, to obtain a high-speed CMOS device, it is necessary to form channels having different plane orientations or channels formed with different semiconductor materials. In a case where a structure formed with materials having different lattice constants from each other is produced through epitaxial growth, crystalline defects are always caused in the epitaxially grown layer near the hetero-junction as the junction plane, and the crystallinity of the epitaxially grown layer deteriorates. Therefore, it is difficult to obtain an epitaxially grown layer having excellent crystallinity, without a decrease in the degree of integration. As the crystallinity deteriorates, the device operation speed also decreases.

With homo-epitaxial growth where the seed portion and the epitaxial growth portion are made of the same material, the crystallinity of the interface portion is also poor. As in the case with the above described hetero-epitaxial growth, it is difficult to achieve high device integration and a high-speed operation at the same time through homo-epitaxial growth.

### SUMMARY OF THE INVENTION

The present invention has been made in view of these circumstances, and an object thereof is to provide a semiconductor device that has epitaxially grown layers with excellent crystallinity, and a method for manufacturing the semiconductor device.

A semiconductor device according to a first aspect of the present invention includes: a semiconductor layer having crystallinity; a first insulating film formed on the semiconductor layer and having a first opening to reach the semiconductor layer; a first epitaxially grown layer formed on the first insulating film so as to embed the first opening; a second insulating film formed on the first epitaxially grown layer and having a second opening to reach the first epitaxially grown layer; and a second epitaxially grown layer formed on the second insulating film so as to embed the second opening.

A semiconductor device according to a second aspect of the present invention includes: a first semiconductor layer; a first insulating film formed on the first semiconductor layer and having a first region, a second region, and a first opening, the first opening being formed in the second region and reaching the first semiconductor layer; a second semiconductor layer formed on the first region and having a plane orientation not equivalent to a plane orientation of the first semiconductor layer; a MOSFET of a first conductivity type formed on the second semiconductor layer; a first epitaxially grown layer formed on the second region so as to embed the first opening; a second insulating film formed on the first epitaxially grown layer and having a second opening to reach the first epitaxially grown layer; a second epitaxially grown layer formed on the second insulating film so as to embed the second opening; and a MOSFET of a second conductivity type formed on the second epitaxially grown layer

A method for manufacturing a semiconductor device according to a third aspect of the present invention includes: forming a first opening in a first insulating film formed on a semiconductor layer having crystallinity, the first opening reaching the semiconductor layer; forming a first epitaxially grown layer on the first insulating film so as to embed the first opening; forming a second insulating film on the first epitaxially grown layer; forming a second opening in the second insulating film, the second opening reaching the first epitaxially grown layer; and forming a second epitaxially grown layer on the second insulating film so as to embed the second opening.

### BRIEF DESCRIPTION OF THE DRAWINGS

FIGS. 1 to 8 are cross-sectional views showing a procedure for manufacturing a semiconductor device in accordance with a first embodiment of the present invention;

FIG. 9 is a cross-sectional view of a semiconductor device in accordance with a second embodiment of the present invention;

FIG. 10 is a cross-sectional view of a semiconductor device in accordance with a third embodiment of the present invention;

FIG. 11 is a plan view of a semiconductor device in accordance with a fourth embodiment of the present invention;

FIG. 12 is a plan view of a semiconductor device in accordance with a first modification of the fourth embodiment;

FIG. 13 is a plan view of a semiconductor device in accordance with a third modification of the fourth embodiment;

FIG. 14 is a plan view of a semiconductor device in accordance with a fourth modification of the fourth embodiment;

FIG. 15 is a plan view of a semiconductor device in accordance with a fifth modification of the fourth embodiment;

FIG. 16 is a plan view of a semiconductor device in accordance with a sixth modification of the fourth embodiment; and

FIGS. 17 to 22 are cross-sectional views showing a procedure for manufacturing a semiconductor device in accordance with a fifth embodiment.

### DETAILED DESCRIPTION OF THE INVENTION

The following is a description of embodiments of the present invention, with reference to the accompanying drawings. It should be noted that identical components are denoted by identical reference numerals in the following embodiments, and explanation of identical components will not be made more than once. Each of the drawings is a schematic view drawn to facilitate explanation and understanding of the invention, and the shapes, sizes and proportions shown in the drawings may differ from those of the actual devices.

### First Embodiment

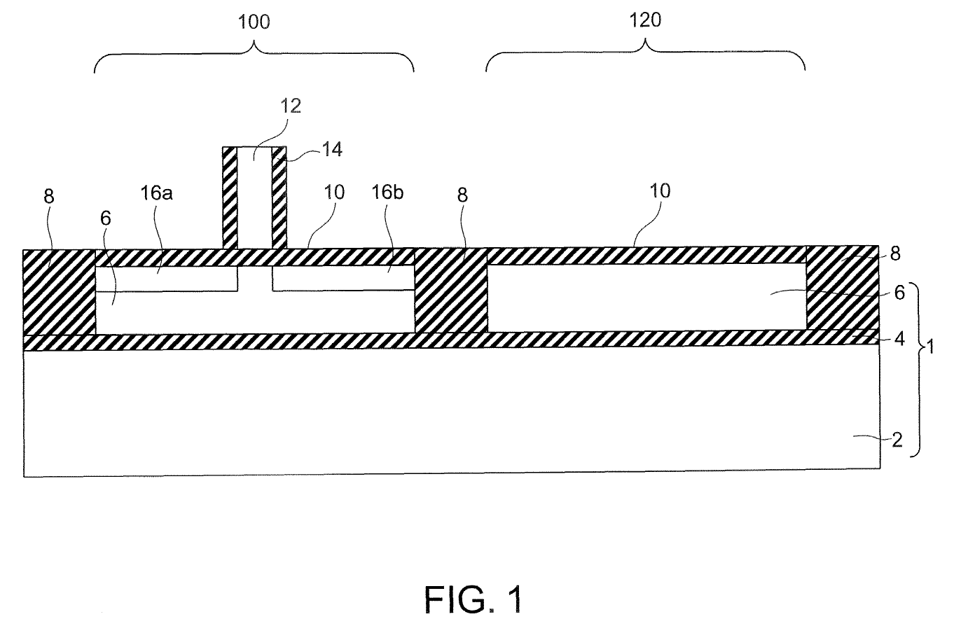

Referring to FIGS. 1 through 8, a semiconductor device in accordance with a first embodiment of the present invention is described. The semiconductor device of this embodiment has a structure in which a SOI substrate is formed with a supporting substrate and a SOI layer having different plane orientations from each other, an n-type MOSFET is formed on the SOI layer, a Ge layer is formed by virtue of the plane orientation of the supporting substrate, and a p-type MOSFET is formed on the Ge layer. In the following, a method for manufacturing the semiconductor device of this embodiment is described.

First, as shown in FIG. 1, a SOI substrate 1 that includes a supporting substrate 2 made of single-crystal silicon having the (110) plane orientation, a buried oxide film (BOX layer) 4, and a SOI layer 6 made of single-crystal silicon having the (100) plane orientation, is prepared. After STI (Shallow Trench Isolation) layers 8 for isolating each region 100 in which an n-type MOSFET is formed from each region 120 in which a p-type MOSFET is formed are formed on the SOI layer 6, a gate insulating film 10 is formed on the SOI layers 6 of the region 100 in which an n-type MOSFET is formed and on the SOI layer 6 of the region 120 in which a p-type MOSFET is formed. The region 120 in which a p-type MOSFET is formed is then covered with a resist (not shown). After that, a gate electrode 12 is formed over the region 100, and gate sidewalls 14 made of an insulating material are formed on the sides of the gate electrode 12. Source/drain regions 16a and 16b are then formed by implanting n-type impurities into the SOI layer 6 located on both sides of the gate electrode 12 (see FIG. 1). In this manner, an n-type MOSFET is formed in the region 100.

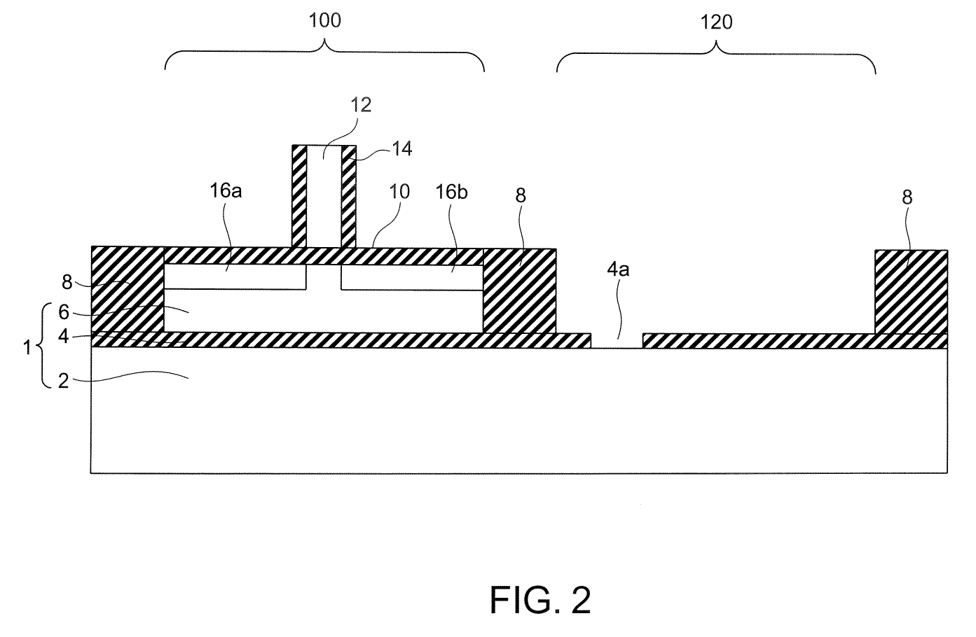

After the resist covering the region 120 is removed, the region 100 having the n-type MOSFET formed therein is masked with a resist (not shown). The gate insulating film 10 and the SOI layer 6 located in the region 120 in which a p-type MOSFET is formed are removed by an exposure and etching process, as shown in FIG. 2, and an opening 4a is formed in the buried oxide film 4 in the vertical direction (the film thickness direction) of the buried oxide film 4.

The manufacturing procedures thereafter concerns only the formation of a p-type MOSFET, and therefore, only the region 120 in which the p-type MOSFET is formed is shown in the following drawings.

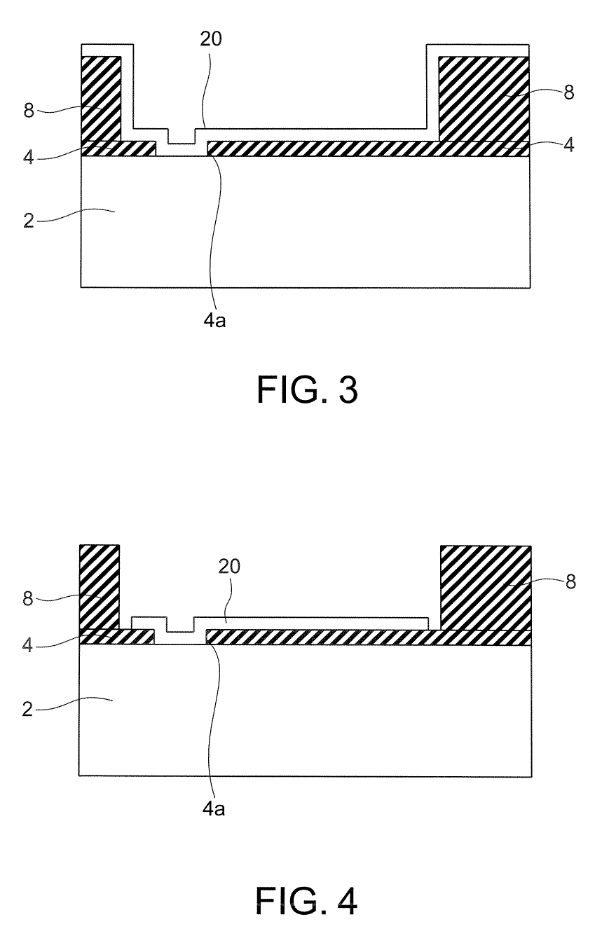

As shown in FIG. 3, a Ge layer 20 in an amorphous state is deposited by a sputtering technique on the entire substrate, so as to fill the opening 4a. The Ge layer 20 in an amorphous state is epitaxially grown to be a single-crystal Ge layer 20. Patterning is then performed on the single-crystal Ge layer 20 by a lithography technique, so that the single-crystal Ge layer 20 remains only on the portion of the region 120 in which a p-type MOSFET is formed (see FIG. 4).

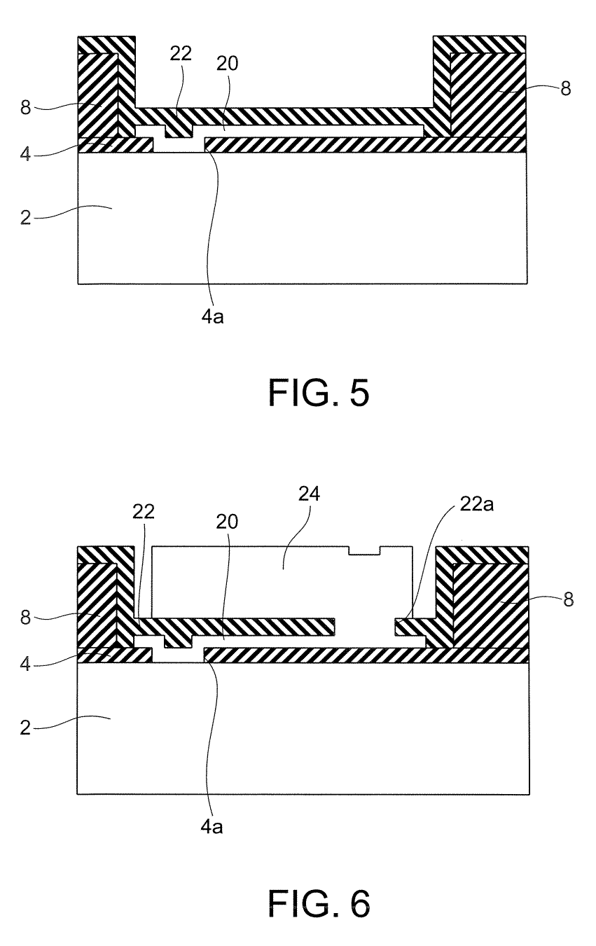

A SiO₂ film 22 is then deposited on the entire substrate surface with the use of a MOCVD (Metal Organic Chemical Vapor Deposition) device (see FIG. 5). After when an opening 22a exposing the single-crystal Ge layer 20 at the bottom is formed in the SiO₂ film 22 in the vertical direction of the SiO₂ film 22, as shown in FIG. 6, a Ge layer in an amorphous state is deposited to fill the opening 22a by a sputtering technique. Here, the opening 22a formed in the SiO₂ film 22 is located in a position at a distance in the film plane direction (the direction perpendicular to the film thickness direction) from the opening 4a formed in the buried oxide film 4. The Ge layer in an amorphous state is then epitaxially grown into a single-crystal Ge layer. After that, patterning is performed on the single-crystal Ge layer by a lithographic technique, so that the single-crystal Ge layer remains only on the p-type MOSFET formation region 120. Thus, a single-crystal Ge region 24 is formed (see FIG. 6).

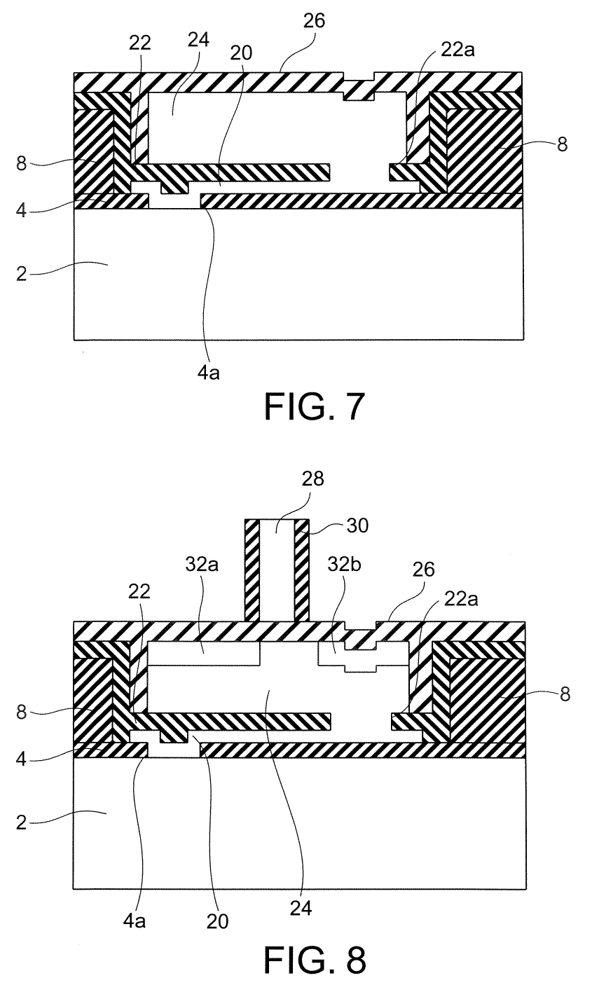

A gate insulating film 26 made of a high-dielectric material (a Zr silicate film, for example) is deposited on the entire substrate surface with the use of a MOCVD device (see FIG. 7). A gate electrode 28 is then formed on the gate insulating film 26, as shown in FIG. 8. The gate electrode 28 serving as a mask, impurity ions are implanted into the Ge region, thereby source/drain regions 32a and 32b are formed. Gate sidewalls 30 made of an insulating material are then formed on the sides of the gate electrode 28. Thus, a p-type MOSFET is completely formed on the Ge region 24 (see FIG. 8).

As described above, in this embodiment, the Ge layer 20 as an epitaxially grown layer is formed through the opening 4a provided in the buried oxide film 4 in its vertical direction from the supporting substrate 2, thereby a Ge region 24 as the epitaxially grown layer on which a p-type MOSFET is formed through an opening 22a provided in the SiO₂ film 22 in its vertical direction from the Ge layer 20. Thus, even if there is a crystalline defect in the hetero-junction plane between the Ge layer 20 and the supporting substrate 2 as a bottom portion of the opening 4a to be a seed portion, the crystalline defect formed during the epitaxial growth can be prevented as much as possible from transmitting to the upper layers through the openings 4a and 22a. Accordingly, the crystallinity of the outermost face of the Ge region 24 is excellent. The single-crystal Ge region 24 has the [110] orientation, reflecting the information of the (110) plane of the Si of the supporting substrate 2 to be the seed portion. The single-crystal Ge region 24 has a different orientation from the [100] orientation of the Si of the region 100 in which an n-type MOSFET is formed. Since the opening 4a and the opening 22a are formed at a distance from each other in the film plane direction (the direction perpendicular to the film thickness direction), even if a crystalline defect is formed in the Ge layer 20 in contact with the supporting substrate 2 forming the bottom portion of the opening 4a to be the seed portion, the probability of the crystalline defect reaching the outermost face of the single-crystal Ge region 24 can be lowered.

As described above, in accordance with this embodiment, devices can be formed on the epitaxially grown layers 6 and 24 that have excellent crystallinity and different plane orientations and materials from each other. With this arrangement, the devices can be operated at high speeds. Also, since the epitaxially grown layer 24 with excellent crystallinity can be formed on the entire p-type MOSFET formation region 120, so that a highly-integrated device can be produced. In this embodiment, after an n-type MOSFET is formed on the Si single-crystal region 6, the single-crystal Ge region 24 is formed, and a p-type MOSFET is formed on the Ge region 24. With this arrangement, a difference in processing temperature that is the problem caused when a device formed on a Si semiconductor and a device formed on a Ge semiconductor are mounted together can be prevented.

In this embodiment, the crystal orientation of the seed portion, which is the supporting substrate 2, can be arbitrarily set, independently of the region in which an n-type MOSFET is formed. The seed portion is not necessarily made of single-crystal Si, and may be made of polycrystalline Si, a silicide, a metal or an insulating crystalline material such as alumina, which has regular crystallinity.

In this embodiment, the single-crystal Ge is formed immediately after the deposition of a Ge layer in an amorphous state through epitaxial growth. However, it is also possible to form the single-crystal Ge after the formation of the Ge region 24 in an amorphous state and before the impurity ion implantation, while leaving the Ge layer 20 in an amorphous state. Alternatively, it is possible to form the single-crystal Ge after the ion implantation. In any of those cases, epitaxial growth needs to be performed only once, which is advantageous. Instead of epitaxial growth, the single-crystal Ge may be formed through liquid phase epitaxy (LPE) at 940° C.

Generally, Ge has poorer heat conductance than Si. For instance, in a 27° C. atmosphere, the heat conductance of Si is 1.5 W/cm° C., while the heat conductance of Ge is 0.6 W/cm° C. Further, the SOI device region is surrounded by the buried insulating layer 4 made of SiO₂ having even poorer heat conductance (0.014 W/cm° C.) and the STI layer 8. Because of this, heat tends to stay in the SOI device region. As a result, the device formed on the SOI layer made of Ge has a lower operation speed as the temperature rises during an operation.

In this embodiment, on the other hand, the heat generated in the Ge region 24 is released toward the Si supporting substrate 2. Accordingly, the p-type MOSFET formed on the Ge region 24 can maintain high-speed device operations.

In this embodiment, as the insulating film 22 on the Ge region 24, a film deposited with the use of a MOCVD device is employed. However, a film formed with another deposition device may be used, or the insulating film 22 may be formed by oxidizing or nitriding Ge. Particularly, in a case where the insulating film 22 is made of Si₃N₄ or Ge₃N₄, or is formed by nitriding Si, Ge, or a Si oxide, or a Ge oxide, the epitaxial layers are expected to have excellent crystallinity.

Although Ge is used as the material for the epitaxially grown regions in this embodiment, it is possible to employ Si or a III-V group semiconductor such as SiGe, GaAs, GaN, InSb, or InP with a given composition. Also, the plane orientation can be arbitrarily set by selecting the plane orientation for the supporting substrate. In principle, the materials and compositions for the first epitaxially grown layer 20 and the second epitaxially grown layer 24 can be changed. Although two epitaxially grown layers are formed in this embodiment, it is possible, in principle, to form more than two.

### Second Embodiment

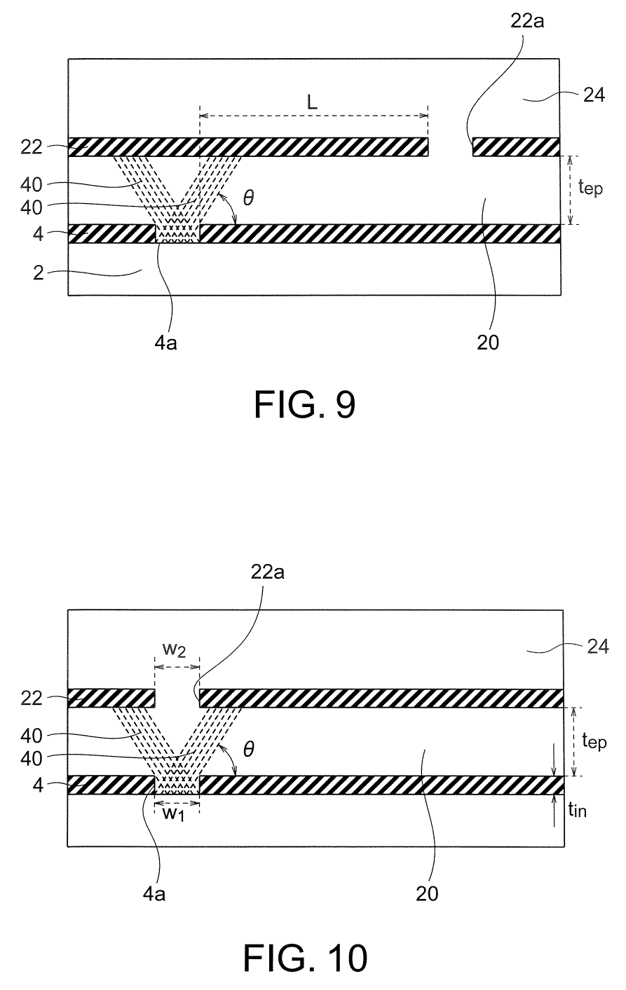

Referring now to FIG. 9, a semiconductor device in accordance with a second embodiment of the present invention is described.

The semiconductor device of this embodiment is substantially the same as the semiconductor device of the first embodiment, except that the film thickness M of the epitaxially grown layer 20 and the distance L in the film plane direction between the opening 22a formed in the insulating film 22 and the opening 4a formed in the buried oxide film layer 4 satisfies the following conditions. More specifically, there is relationship between the film thickness tₑₚ of the epitaxially grown layer 20 and the distance L between openings formed in the insulating films 4 and 22:

tₑₚ<L×tan θ

where θ represents the angle of a (111) plane to be a slip plane 40 with respect to the film plane of the epitaxially grown layer 20. In a case where the epitaxially grown layer 20 has a (100) plane orientation, the angle θ is 54.7°. In a case where it has the (110) plane orientation, the angle θ is 35.30° In a case where it has the (111) plane orientation, the angle θ is 70.5°. Crystalline defects are normally caused along a slip plane. Accordingly, with the geometric arrangement employed in this embodiment, the slip plane 40 extending from the opening 4a can reach the insulating film 22 before reaching the opening 22a. Thus, crystalline defects formed at the hetero-junction of the opening 4a can be terminated at the insulating film 22 before reaching the opening 22a, and crystalline defects in the Ge region 24 can be prevented.

As described above, the semiconductor device of this embodiment can prevent the occurrence of a crystalline defect in the Ge region 24 more effectively than the semiconductor device of the first embodiment.

### Third Embodiment

Referring now to FIG. 10, a semiconductor device in accordance with a third embodiment of the present invention is described.

The semiconductor device of this embodiment is substantially the same as the semiconductor device of the first embodiment, except that there is the following relationship among the film thickness tₑₚ of the epitaxially grown layer 20, the thickness tᵢₙ of the insulating film 4, and the opening width w₁ of the opening 4a formed in the buried oxide film layer 4:

(tᵢₙ+tₑₚ)≧w₁×tan θ

With this arrangement, at least a part of the opening 22a formed in the insulating film 22 exists vertically above the opening 4a.

Here, θ represents the angle of the (111) plane 40 with respect to the epitaxially grown layer 20. In a case where the epitaxially grown layer 20 has the (100) plane orientation, the angle θ is 54.7°. In a case where it has the (110) plane orientation, the angle θ is 35.3°. In a case where it has the (111) plane orientation, the angle θ is 70.5°. In the case of the (110) plane orientation, however, the (111) plane might be at 90°, which is at right angle, with respect to the (110) plane, and in this case, an opening should not be formed in the device region.

With the geometric arrangement employed in this embodiment, crystalline defects formed at the hetero-junction of the opening 4a can be terminated at the insulating film 22 before reaching the opening 22a, and crystalline defects in the Ge region 24 can be prevented.

As described above, the semiconductor device of this embodiment can prevent the occurrence of a crystalline defect in the Ge region 24 more effectively than the semiconductor device of the first embodiment.

Also, in this embodiment, the same mask is used to form the openings in the insulating films 4 and 22. Accordingly, the production costs can be lowered.

### Fourth Embodiment

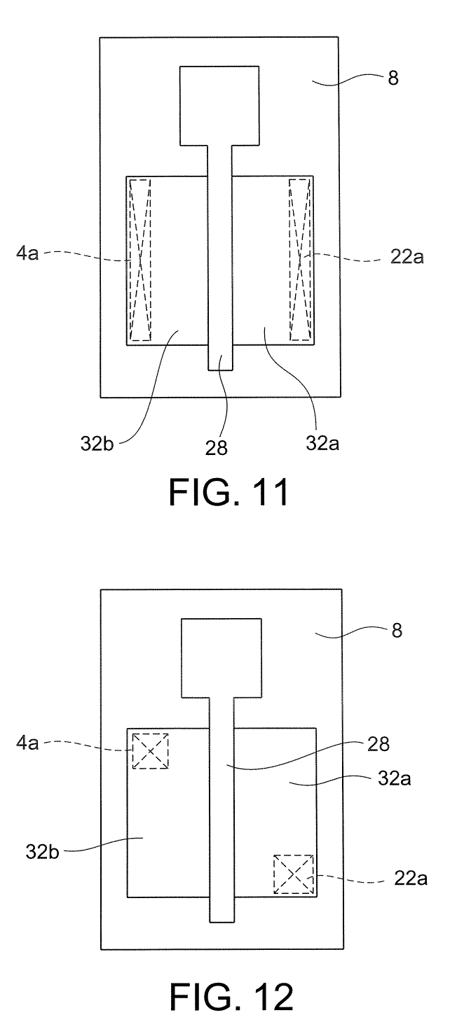

Referring now to FIG. 11, a semiconductor device in accordance with a fourth embodiment of the present invention is described.

The semiconductor device of this embodiment differs from the semiconductor device of the first embodiment in that the locations of the opening 4a and the opening 22a are geometrically defined on a plan view. In this embodiment, the opening 4a is formed immediately below the drain region 32b, and the opening 22a is formed immediately below the source region 32a, as shown in FIG. 11. The depletion layer on the drain side of a MOSFET has a greater width than the depletion layer on the source side, and a crystalline defect in the depletion layer increases junction leakage and power consumption. Therefore, the opening 22a closer to the surface of the Ge region 24 on which a MOSFET is formed is located on the side of the source region 32a in this embodiment, so as to solve the above problem.

Particularly, in a first modification of this embodiment shown in FIG. 12, the openings 4a and 22a are diagonally arranged, so as to elongate a distance between the openings 4a and 22a. In this manner, the probability of crystalline defects reaching the epitaxially grown layer 24 on the outermost surface can be reduced.

In a second modification of this embodiment, the positions of the openings shown in FIG. 11 are reversed. More specifically, the opening 22a is formed immediately below the drain region 32b, and the opening 4a is formed immediately below the source region 32a. In this modification, the drain region 32b can be placed at a distance from the opening 22a of the epitaxially grown layer 24 in which a channel is formed. Accordingly, the device is less affected by the crystalline defects near the opening, and an excellent pn junction can be formed.

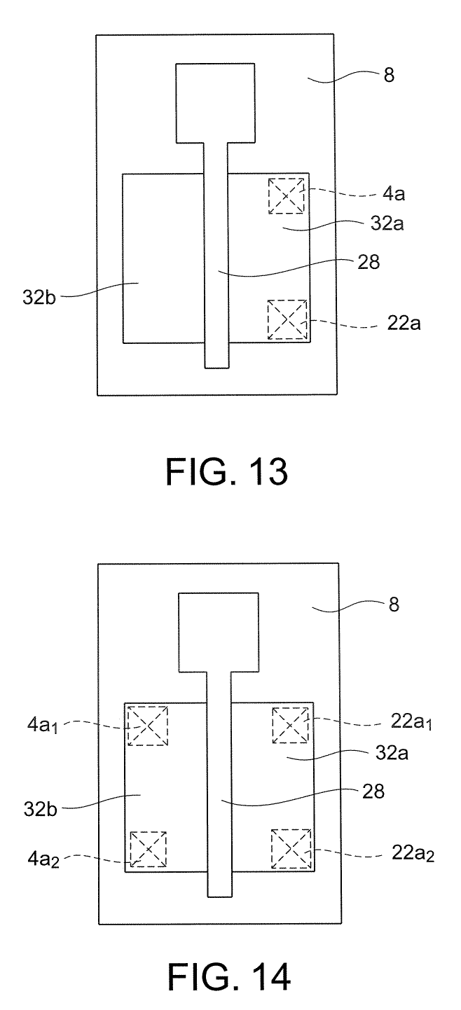

In a third modification of this embodiment shown in FIG. 13, the openings 4a and 22a may be formed only in the source region 32a or only in the drain region 32b. With this arrangement, the distance between the openings 4a and 22a is shorter. Accordingly, the heat generated during a device operation is easily released, and the device operation is made stable.

In a fourth modification of this embodiment shown in FIG. 14, a plurality of openings is provided in each of the source region 32a and the drain region 32b. More specifically, openings 22a₁ and 22a₂ formed in the insulating film 22 are located in the source region 32a, and openings 4a₁ and 4a₂ formed in the insulating film 4 are located in the drain region 32b. With this arrangement, the epitaxial growth time can be shortened.

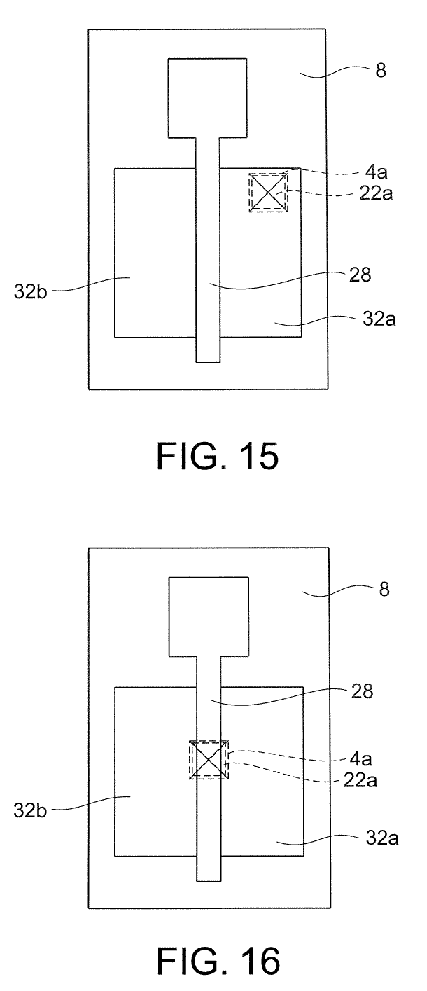

In a fifth modification of this embodiment shown in FIG. 15, the opening 22a is located immediately above the opening 4a, and the openings 4a and 22a may be located in the source region 32a. In this modification, the locations of the openings 4a and 22a in the semiconductor device of the third embodiment are more clearly defined. In this modification, only one mask is required for forming the openings, as in the third embodiment.

In a sixth modification of this embodiment shown in FIG. 16, the opening 22a is located immediately above the opening 4a, and the openings 4a and 22a are located immediately below the gate electrode 28. In this modification, the openings 4a and 22a are located substantially at the center of the device. Accordingly, the length of the epitaxial growth in the transverse direction can be reduced, and epitaxial layers with excellent crystallinity can be easily formed. As in the fifth modification, only one mask is required for forming the openings in this modification.

### Fifth Embodiment

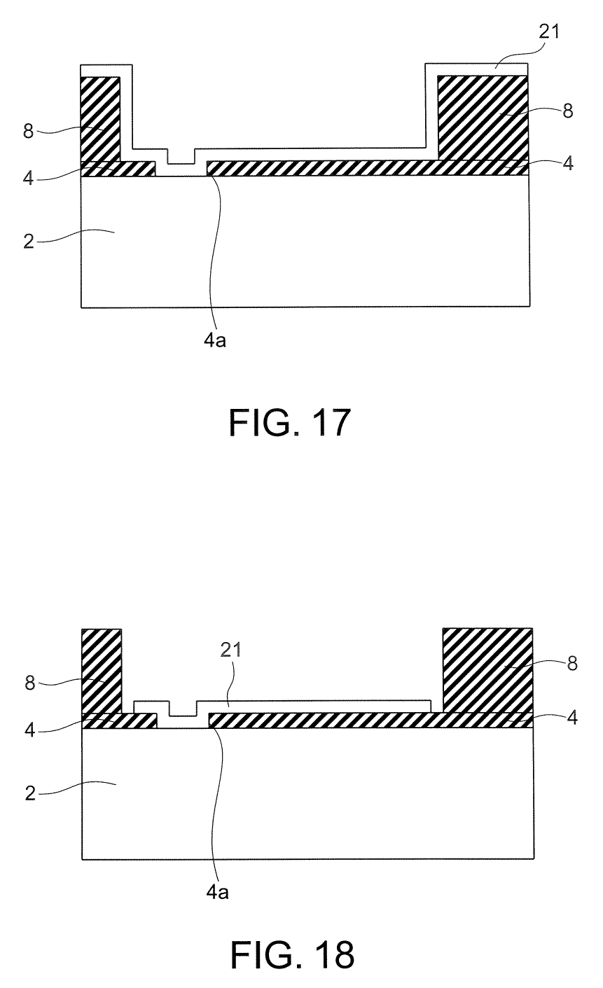

Referring now to FIGS. 17 through 22, a semiconductor device in accordance with a fifth embodiment of the present invention is described. The semiconductor device of this embodiment is the same as the semiconductor device of the first embodiment, except that the epitaxially grown layers 20 and 24 containing Ge are replaced epitaxially grown layers 21 and 25 containing Si.

The semiconductor device of this embodiment is formed in the following manner.

First, the same procedures as those of the first embodiment are carried out until the opening 4a is formed in the buried oxide film 4.

A Si layer 21 in an amorphous state is then deposited on the entire substrate surface by a sputtering technique, so as to fill the opening 4a, as shown in FIG. 17. The Si layer 21 in an amorphous state is epitaxially grown into a single-crystal Si layer 21. Patterning is performed on the single-crystal Si layer 21 by a lithography technique, so that the single-crystal Si layer 21 remains only in the region 120 in which a p-type MOSFET is formed (see FIG. 18).

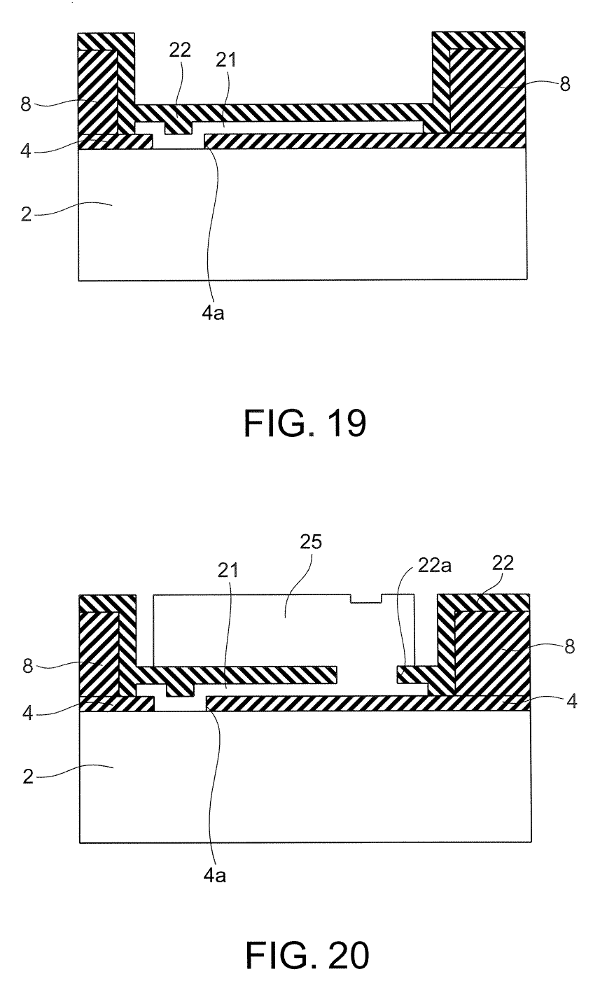

Next, a SiO₂ film 22 is deposited on the entire substrate surface with the use of a MOCVD (Metal Organic Chemical Vapor Deposition) device (see FIG. 19). After a vertical opening 22a to expose the single-crystal Si layer 21 at its bottom is formed in the SiO₂ film 22, a Si layer in an amorphous state is deposited on the entire substrate surface by a sputtering technique, so as to fill the opening 22a, as shown in FIG. 20. The opening 22a formed in the SiO₂ film 22 is formed in a position at a distance in the film plane direction from the opening 4a formed in the buried oxide film 4. The Si layer in an amorphous state is then epitaxially grown into a single-crystal Si layer. After that, patterning is performed on the single-crystal Si layer by a lithography technique, so that the single-crystal Si layer remains only in the region 120 in which a p-type MOSFET is formed. In this manner, a single-crystal Si region 25 is formed (see FIG. 20). Here, the Si region 25 has the same plane orientation as the (110) plane orientation of the supporting substrate 2, as in the first embodiment.

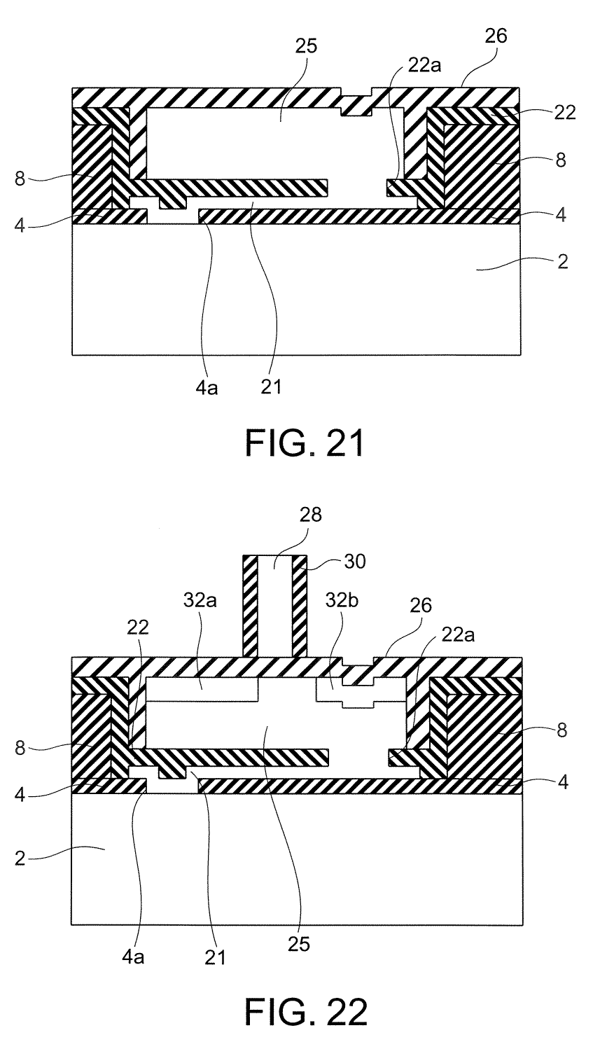

Next, a gate insulating film 26 made of a high-dielectric material (a Zr silicate film, for example) is deposited on the entire substrate surface with the use of a MOCVD device (see FIG. 21). A gate electrode 28 is then formed on the gate insulating film 26, as shown in FIG. 22. With the gate electrode 28 serving as a mask, impurity ions are implanted into the Si region 25, so as to form source/drain regions 32a and 32b. Further, gate sidewalls 30 made of an insulating material are formed on the sides of the gate electrode 28. In this manner, a p-type MOSFET is completely formed on the Si region 25 having the (110) plane orientation (see FIG. 22).

As in the first embodiment, devices can be formed on the Si epitaxially grown layers 6 and 25 that have excellent crystallinity and different plane orientations from each other. Accordingly, the devices can be operated at high speeds. Also, the epitaxially grown layer 25 with excellent crystallinity is formed substantially on the entire p-type MOSFET formation region 120. Thus, high integration can be achieved.

It should be understood that the opening 4a and the opening 22a in the semiconductor device of this embodiment may have such a relationship as any of those in the second through fourth embodiments.

As described so far, in accordance with each of the embodiments of the present invention, devices can be formed on epitaxially grown layers having excellent crystallinity. Thus, high-speed device operations can be achieved.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concepts as defined by the appended claims and their equivalents.

What is claimed is:

1. A semiconductor device comprising:
a semiconductor layer having crystallinity;
a first insulating film formed on the semiconductor layer and having a first opening to reach the semiconductor layer;
a first epitaxially grown layer formed on the first insulating film so as to embed the first opening;
a second insulating film formed on the first epitaxially grown layer and having a second opening to reach the first epitaxially grown layer; and
a second epitaxially grown layer formed on the second insulating film so as to embed the second opening.

2. The device according to claim 1, wherein:
the first opening and the second opening are formed apart from each other in a film plane direction; and
a relationship, tₑₚ<L×tan θ, is satisfied where tₑₚ represents a film thickness of the first epitaxially grown layer, L represents a distance between the first and second openings in the film plane direction, and θ represents an angle of a slip plane of the first epitaxially grown layer with respect to the film plane of the first epitaxially grown layer.

3. The device according to claim 1, wherein:
the second opening is designed to overlap the first opening at least partially, when seen from a film thickness direction; and
a relationship, (tᵢₙ+tₑₚ)≧w₁×tan θ, is satisfied where tₑₚ represents a film thickness of the first epitaxially grown layer, tᵢₙ represents a film thickness of the first insulating film, θ represents an angle of a slip plane of the first epitaxially grown layer with respect to a film plane of the first epitaxially grown layer, and w₁ represents an opening width of the first opening.

4. The device according to claim 1, wherein the semiconductor layer is a single-crystal layer.

5. The device according to claim 1, wherein the first and second epitaxially grown layers have a lower melting point than the semiconductor layer.

6. The device according to claim 1, wherein the semiconductor layer contains Si as a main component, and the first and second epitaxially grown layers contain Ge as a main component.

7. The device according to claim 1, further comprising
a MOSFET that is formed on the second epitaxially grown layer.

8. The device according to claim 7, wherein the first opening is formed immediately below a drain region of the MOSFET and the second opening is formed immediately below a source region of the MOSFET.

9. A semiconductor device comprising:
a first semiconductor layer;
a first insulating film formed on the first semiconductor layer and having a first region, a second region, and a first opening, the first opening being formed in the second region and reaching the first semiconductor layer;
a second semiconductor layer formed on the first region and having a plane orientation not equivalent to a plane orientation of the first semiconductor layer;
a MOSFET of a first conductivity type formed on the second semiconductor layer;
a first epitaxially grown layer formed on the second region so as to embed the first opening;
a second insulating film formed on the first epitaxially grown layer and having a second opening to reach the first epitaxially grown layer;
a second epitaxially grown layer formed on the second insulating film so as to embed the second opening; and
a MOSFET of a second conductivity type formed on the second epitaxially grown layer.

10. The device according to claim 9, wherein:
the first opening and the second opening are formed apart from each other in a film plane direction; and
a relationship, tₑₚ<L×tan θ, is satisfied where tₑₚ represents a film thickness of the first epitaxially grown layer, L represents a distance between the first and second openings in the film plane direction, and θ represents an angle of a slip plane of the first epitaxially grown layer with respect to the film plane of the first epitaxially grown layer.

11. The device according to claim 9, wherein:
the second opening is designed to overlap the first opening at least partially, when seen from a film thickness direction; and
a relationship, (tᵢₙ+tₑₚ)≧w₁×tan θ, is satisfied where tₑₚ represents a film thickness of the first epitaxially grown layer, tᵢₙ represents a film thickness of the first insulating film, θ represents an angle of a slip plane of the first epitaxially grown layer with respect to a film plane of the first epitaxially grown layer, and w₁ represents an opening width of the first opening.

12. The device according to claim 9, wherein the first semiconductor layer is a single-crystal layer.

13. The device according to claim 9, wherein the first and second epitaxially grown layers have a lower melting point than the first semiconductor layer.

14. The device according to claim 9, wherein the first and second semiconductor layers contain Si as a main component, and the first and second epitaxially grown layers contain Ge as a main component.

15. The device according to claim 9, wherein the first and second semiconductor layers contain Si as a main component, and the first and second epitaxially grown layers contain Si as a main component.

16. The device according to claim 9, wherein the MOSFET of the first conductivity type is an n-type MOSFET and the second semiconductor layer has a (100) plan orientation, and the MOSFET of the second conductivity type is an p-type MOSFET and the first semiconductor layer has a (110) plan orientation.

17. A method for manufacturing a semiconductor device, comprising:
forming a first opening in a first insulating film formed on a semiconductor layer having crystallinity, the first opening reaching the semiconductor layer;
forming a first epitaxially grown layer on the first insulating film so as to embed the first opening;
forming a second insulating film on the first epitaxially grown layer;
forming a second opening in the second insulating film, the second opening reaching the first epitaxially grown layer; and
forming a second epitaxially grown layer on the second insulating film so as to embed the second opening.

18. The method according to claim 17, wherein the first and second epitaxially grown layers have a lower melting point than the semiconductor layer.

19. The method according to claim 17, wherein the semiconductor layer contains Si as a main component, and the first and second epitaxially grown layers contain Ge as a main component.

20. The method according to claim 17, wherein the semiconductor layer contains Si as a main component, and the first and second epitaxially grown layers contain Si as a main component.
